(19) United States
(12) Patent Application Publication
(10) Pub. No.: US 2026/0006912 A1
(43) Pub. Date: Jan. 1, 2026

(54) SIGE NANORIBBONS FOR HIGH PERFORMANCE TRANSISTORS

(71) Applicant: Intel Corporation, Santa Clara, CA (US)

(72) Inventors: Vijay Saradhi Mangu, Sunnyvale, CA (US); Anand Murthy, Portland, OR (US); Wonil Chung, Hillsboro, OR (US); Tahir Ghani, Portland, OR (US); Kelsey Jorgensen, Beaverton, OR (US); Susmita Ghose, Hillsboro, OR (US); Glenn Glass, Portland, OR (US)

(73) Assignee: Intel Corporation, Santa Clara, CA (US)

(21) Appl. No.: 18/759,243

(22) Filed: Jun. 28, 2024

(51) Int. Cl. H01L 27/092; H01L 21/225; H01L 21/8238; H01L 29/06; H01L 29/423; H01L 29/66; H01L 29/775; H01L 29/786

(52) U.S. Cl. CPC H10D 84/856; H01L 21/2255; H10D 30/014; H10D 30/43; H10D 30/6735; H10D 30/6757; H10D 62/121; H10D 84/0167; H10D 84/038

(57) ABSTRACT

Manufacturing integrated circuit (IC) devices having adjacent transistors with different channel materials. A transistor includes a stack of nanoribbons coupling source and drain bodies, and a nanoribbon has a thickness at a midpoint of the nanoribbon greater than a thickness away from the midpoint. A second transistor may include a stack of nanoribbons coupling source and drain bodies, and the first transistor nanoribbons may have larger thickness variations than the second transistor nanoribbons. The first transistor nanoribbons may have a first element also in the second transistor nanoribbons and a second element absent in the second transistor nanoribbons. The second element may be added into the first transistor nanoribbons by depositing on the first transistor nanoribbons a layer having the second element, depositing a retaining layer over the second-element layer, and diffusing the second element into the first transistor nanoribbons.

### BACKGROUND

While strain on a transistor channel can increase the mobility of charge carriers through the channel, the delivery of strain on channels is difficult or diminished in some transistor structures, e.g., in certain types of transistors. For example, in gate-all-around (GAA) field-effect transistors (FETs) (e.g., with nanowire channels), uniaxial stress is not exerted (or at least not to the same extent, relative to FinFETs) by source and drain epitaxial bodies grown from the ends of channels. With multiple nanowires between epi bodies in GAA FETs, source and drain bodies may be merged, polycrystalline bodies with multiple faults or dislocations that preclude the provision of satisfactory strain by source and drain bodies, which may limit carrier mobilities in some transistor structures.

In some integrated circuit (IC) devices, different groups of transistors may benefit from the use of different materials. For example, p-type FETs may benefit from silicon germanium channel materials, while pure silicon channels may work better in n-type FETs. However, the fabrication of adjacent transistors having different channel materials may be excessively complex and/or costly.

New techniques, structures, and materials are needed to improve the manufacture and operation of GAA FETs in IC devices.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, 1C, 1D, and 1E illustrate cross-sectional profile views of an integrated circuit (IC) device having transistor structures with channel regions in nanoribbons of different materials, in accordance with some embodiments;

FIG. 2 is a flow chart of methods for forming a nanoribbon with an element added to and interspersed in the nanoribbon lattice, in accordance with some embodiments;

FIGS. 3, 4, 5, 6, 7, 8, and 9 illustrate cross-sectional profile views of an IC device having an added element diffused into the crystal lattices, at various stages of manufacture, in accordance with some embodiments;

FIG. 10 illustrates a diagram of an example data server machine employing an IC device having diffusion-enhanced nanoribbon channels, in accordance with some embodiments; and

FIG. 11 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed for forming, and producing strain in, transistor channels of compound semiconductor materials, including nanoribbons having uniform compositions throughout the nanoribbon volumes.

One or more additive elements may be deposited on and around a transistor channel, for example, a nanoribbon in a gate-all-around (GAA) field-effect transistor (FET). Atoms of the additive element(s) may be introduced into, and thoroughly interspersed in, the crystal lattice of the channel by vacancy-assisted diffusion, e.g., to improve one or more characteristics of the channel. Oxygen (and/or nitrogen, etc.) vacancies may be introduced by a capping layer (for example, a dielectric capping layer) that encases the channel (including the additive element(s)) and retains the vacancy element(s) during diffusion. The capping layer can be removed after the channel elements are completely intermixed into a consistent composition throughout the channel. A thorough diffusion ensures a homogenous composition and precludes adverse effects of an interface between unmatched lattices, such as non-uniform strain, reduced carrier mobilities, and increased leakage current. Even if the initial channel composition is purely elemental (e.g., pure silicon), the final composition of the channel can be tuned by adjusting any of the initial channel thickness and the thickness and/or composition of the deposited layer(s). In some embodiments, the initial channel thickness is reduced before depositing the additive element(s) on the channel.

In some embodiments, the channel is fabricated using conventional materials and/or existing processes, and the channel lattice is then modified by the addition of a new element. For example, germanium atoms may be added to a nanoribbon channel of silicon. The resulting structure may have superior channel qualities due to the general electrical qualities of silicon germanium, as well as the compressive strain caused by the larger lattice constant relative to the preexisting silicon nanoribbon. The alteration of the channel lattice may be especially advantageous given the difficulty in otherwise effecting strain in GAA FET channels between merged source and drain bodies.

In the example of germanium added to silicon, the current disclosure allows the use of existing processes (which may conserve known benefits, such as proven reliabilities and reduced costs, relative to other, more disruptive process-flow changes) to produce the silicon nanoribbon. The example also enables the use of one material (e.g., silicon) for one channel type (e.g., nFET) and another material (e.g., silicon germanium) for another channel type (e.g., pFET), which clearly has benefits in CMOS (complementary MOS (metal-oxide-semiconductor)) integrated circuit (IC) devices. The channels of differing materials, with and without the added element(s), may be positioned as channels would be in the established process, for example, parallel and at identical heights in stacks with identical pitches. Besides the compressive effect, silicon germanium otherwise improves pFET performance (e.g., by increasing mobility and reducing threshold voltage V_{T}) and reliability (e.g., having reduced negative-bias temperature instability (NBTI)). Although the example of adding germanium into a lattice of silicon is repeatedly referenced, other materials may be employed (e.g., as an added, diffused element or as an initial lattice) to introduce or alter other characteristics and/or to exert another type or magnitude of strain.

In some embodiments, for example, having nanoribbons with larger atoms diffused into a lattice of smaller atoms, nanoribbons exhibit a tell-tale bulge or thickening near a midpoint of the nanoribbon. The larger atoms inserted into a compact lattice may cause the bulge by expanding the lattice evenly along a length of a nanoribbon, but with the nanoribbon lattice pinned to the previous, smaller lattice constant to source and drain bodies at the nanoribbon ends.

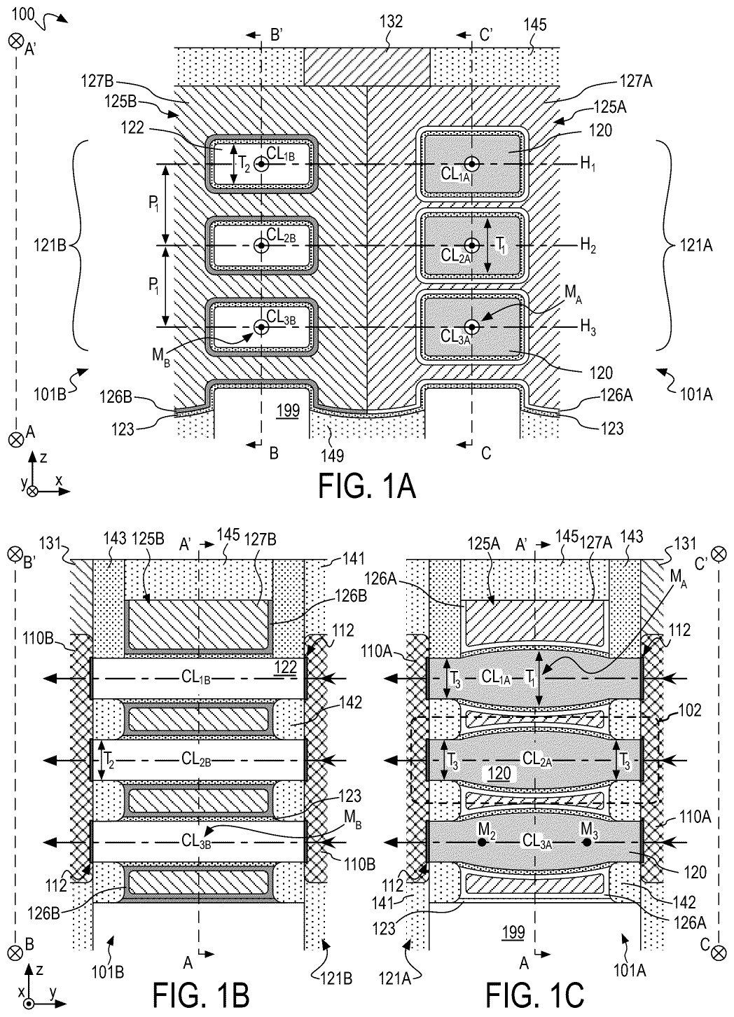

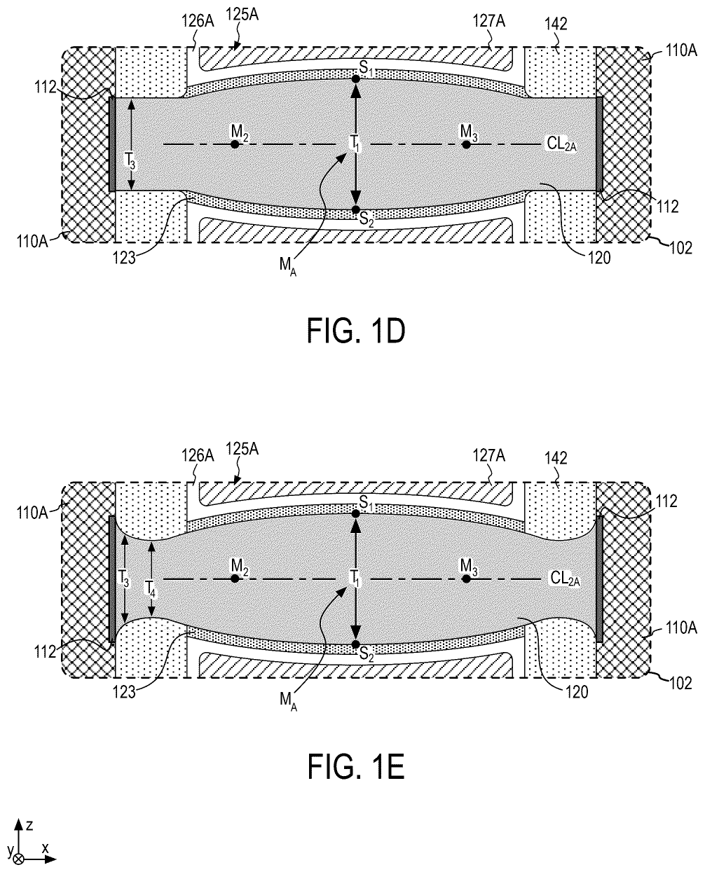

FIGS. 1A, 1B, 1C, 1D, and 1E illustrate cross-sectional profile views of an IC device 100 having transistor structures 101 with channel regions in nanoribbons 120, 122 of different materials, in accordance with some embodiments. FIG. 1A shows the orientation of cross-sectional views B-B′ and C-C′ of FIGS. 1B and 1C. FIGS. 1B and 1C illustrate the orientation of cross-sectional view A-A′ of FIG. 1A. View 102 in FIG. 1C is shown in greater detail in FIGS. 1D and 1E for multiple possible embodiments.

Nanoribbon 120 may include an element not present in nanoribbon 122, e.g., an element that may be added to the lattice of nanoribbon 120 to enhance a characteristic of nanoribbon 120. Nanoribbons 120, 122 have thicknesses T₁, T₂ at the respective midpoints M_{A}, M_{B} of nanoribbons 120, 122. Each of enhanced nanoribbons 120 may include a bulge, for example, with a thickness T₁ at or near midpoint M_{A} of nanoribbon 120 greater than a thickness T₃ at or near an end of nanoribbon 120. Thickness T₁ at or near midpoint M_{A} of nanoribbon 120 may be greater than a thickness T₂ at or near midpoint M_{B} of nanoribbon 122. The bulge may be due to the expanded lattice of nanoribbon 120. Nanoribbon 122 (lacking an element present in the lattice of nanoribbon 120) may have a uniform thickness T₂ along a length of nanoribbon 122 (e.g., at or near midpoint M_{B} and both ends of nanoribbons 122). The uniform thickness T₂ of nanoribbon 122 may be approximately equal to thickness T₃ at or near an end of nanoribbon 120. Nanoribbons 120, 122 may be parallel, at the same heights H₁, H₂, H₃, and separated by the same pitches P₁, which may simplify processing (and so reduce manufacturing costs, e.g., of both time and money).

FIG. 1A shows stacks 121 of nanoribbons 120, 122 in transistor structures 101. Nanoribbons 120, 122 extend in the y-directions through gate electrode 125(s) and the x-z view A-A′ of FIG. 1A, which shows a transverse cross-section of nanoribbons 120, 122. As noted, the figures and their elements are not necessarily illustrated to scale. In other embodiments, nanoribbons 120, 122 may be very narrow or wide (e.g., in the x-direction), e.g., nanowires, nanosheets, etc. Transistor structures 101 include (and nanoribbons 120, 122 couple) source and drain bodies (not shown in FIG. 1A) in front of and behind the x-z viewing plane of FIG. 1A. Transistor structure 101A includes stack 121A of nanoribbons 120 through gate electrode 125A. Transistor structure 101B includes stack 121B of nanoribbons 122 through gate electrode 125B. In the example of FIG. 1A, gate electrodes 125A, 125B are portions of an integrated electrode 125.

Corresponding nanoribbons 120, 122 in stacks 121A, 121B are at same heights, for example, upper nanoribbons 120, 122 at height H₁, lower nanoribbons 120, 122 at height H₃, and nanoribbons 120, 122 at height H₂ between upper and lower nanoribbons 120, 122. Nanoribbons 120, 122 in stacks 121A, 121B are separated by the same pitches P₁, e.g., between heights H₁, H₂ and between heights H₂, H₃. Nanoribbons 120, 122 are all parallel, with centerlines CL extending in the y-directions (e.g., coplanar centerlines CL_{1A}, CL_{1B} at height H₁, coplanar centerlines CL_{2A}, CL_{2B} at height H₂, and coplanar centerlines CL_{3A}, CL_{3B} at height H₃). Coplanar centerlines CL_{1A}, CL_{2A}, CL_{3A} are in the y-z plane of view C-C′ of FIG. 1C and intersect the x-z plane of view A-A′ of FIG. 1A at midpoints M_{A} of nanoribbons 120. Coplanar centerlines CL_{1B}, CL_{2B}, CL_{3B} are in the y-z plane of view B-B′ of FIG. 1B and intersect the x-z plane of view A-A′ of FIG. 1A at midpoints M_{B} of nanoribbons 122.

Nanoribbons 120, 122 include different channel materials. In many embodiments, nanoribbons 120, 122 include complementary channel materials. The channel materials are referred to herein as “complementary” because one channel material is advantageous for an NMOS transistor structure 101 while the other channel material is advantageous for a PMOS transistor structure 101. In exemplary embodiments, channel material within an NMOS transistor structure 101 offers higher electron mobility than the channel material within a PMOS structure 101. In exemplary embodiments, channel material within a PMOS transistor structure 101 likewise offers higher hole mobility than the channel material within a NMOS transistor structure 101. The high complementary carrier mobilities may therefore enable high drive currents independently for both NMOS and PMOS structures 101. For clarity of discussion, in the example of FIGS. 1A-1E, nanoribbons 122 are referred to as being within a channel of NMOS transistor structure 101B while nanoribbons 120 are within a channel of PMOS transistor structure 101A.

In accordance with some embodiments, PMOS and NMOS nanoribbons 120, 122 have complementary chemical compositions where one composition is advantageous for a p-type transistor (e.g., having higher hole mobility) and the other composition is advantageous for an n-type transistor (e.g., having higher electron mobility). For example, nanoribbons 120 may each be a first Group IV, Group III-V, etc., semiconductor material while nanoribbons 122 are each a second Group IV, Group III-V, etc., semiconductor material. In many embodiments, nanoribbons 120 include a semiconductor element absent from nanoribbons 122. In some notable Group IV embodiments, nanoribbons 120 include germanium (e.g., Si_{1-X}Ge_{X}) while nanoribbons 122 include primarily silicon and may consist essentially of silicon (e.g., substantially pure silicon with germanium absent in nanoribbons 122).

In embodiments having nanoribbons 120 of silicon germanium (e.g., Si_{1-X}Ge_{X}), nanoribbons 120 may have any suitable concentration of germanium. In many embodiments, nanoribbons 120 have a germanium concentration of at least 20% and no more than 40%. Advantageously, nanoribbons 120 have an optimized concentration of germanium (e.g., 0.2≤x≤0.4 in Si_{1-X}Ge_{X}) to provide performance and reliability improvements as previously described (e.g., reduced threshold voltage V_{T} and reduced NBTI). Advantageously, nanoribbons 120 have a sufficient concentration of germanium (e.g., ≥20%) to provide, e.g., increased compressive strain and hole mobility. Advantageously, nanoribbons 120 do not have overly high concentrations of germanium (e.g., ≤40%), which might cause dislocations or other lattice defects. An optimal concentration of germanium may vary with nanoribbon 120 geometry.

Advantageously, nanoribbons 120 have a homogenous composition, for example, throughout a length or thickness of nanoribbons 120. In many embodiments, nanoribbons 120 have a same composition (e.g., germanium concentration) along thickness T₁ at midpoint M_{A} (e.g., at the intersection of views A-A′ and C-C′), whether on one of centerlines CL_{1A}, CL_{2A}, CL_{3A} or on a surface over midpoint M_{A} (e.g., at an interface of nanoribbon 120 and gate layer 123). For the purposes of this disclosure, two compositions are considered the same or approximately equal if the various concentrations (e.g., germanium concentrations) are within 5% of each other. For example, in many embodiments, nanoribbons 120 have a same germanium concentration on centerline CL_{1A} at midpoint M_{A} (e.g., of 25% germanium) and on a surface over midpoint M_{A} (e.g., of 30% germanium).

Nanoribbons 120, 122 may have any suitable thicknesses T₁, T₂, for example, about 3 nm, 5 nm, 7 nm, etc. In many embodiments, nanoribbon 120 has a thickness T₁ at midpoint M_{A} more than 5% greater than (e.g., greater than 105% of) thickness T₂ at midpoint M_{B} of nanoribbon 122, for example, due to an additional element in, and the expanded lattice of, nanoribbon 120. A lattice of nanoribbon 120 may expand or strain in multiple directions. For example, although an increase of thickness T₁ is shown in the z-direction, a thickness variation in the x- and z-directions may be increased by strain in the y-directions. A thickness variation in the x-directions may be limited by geometries of nanoribbons 120, e.g., by the comparative widths and heights of nanoribbons 120. Nanoribbons 120, 122 are parallel (e.g., with centerlines CL_{1A}, CL_{2A}, CL_{3A} at the same heights H₁, H₂, H₃ as centerlines CL_{1B}, CL_{2B}, CL_{3B}, respectively) and separated by the same pitches P₁.

One or more gate electrodes 125 are between individual ones of nanoribbons 120. Gate electrode 125 may include one or more insulator materials in a gate layer 123, which provides isolation between nanoribbons 120, 122 and associated gate metals 126, 127. In some embodiments, transistor structures 101A, 101B have distinct gate electrodes 125A, 125B. In some embodiments, transistor structures 101A, 101B share a common gate electrode 125. In some embodiments, one gate electrode 125B is between individual ones of nanoribbons 122. Gate electrode 125B may include one or more gate insulator materials (e.g., in gate layer 123) and one or more gate electrode materials (e.g., workfunction metals 126B, 127B) advantageous for NMOS structure 101B. Another gate electrode 125A is between individual ones of nanoribbons 120. Gate electrode 125A may include one or more gate insulator materials (e.g., in gate layer 123) and one or more gate electrode materials (e.g., workfunction metals 126A, 127A) advantageous for PMOS structure 101A. In some embodiments, gate metals 127A, 127B are workfunction metals 127A, 127B. In some embodiments, gate electrode 125B includes a first high-K (“high-permittivity”) insulator material advantageous for n-type transistor structures 101B and a first workfunction metal advantageous for n-type transistor structures 101B while gate electrode 125A includes a second high-K insulator material advantageous for p-type transistor structures 101A and a second workfunction metal advantageous for p-type transistor structures 101A.

Exemplary high-K dielectrics (e.g., in gate layer 123) include metal oxides (e.g., including one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate), or metal silicates (e.g., including one or more of above metals, oxygen and silicon). Examples of work function metals (e.g., in gate electrode 125) include ruthenium, palladium, platinum, cobalt, nickel, and conductive metal oxides (e.g., ruthenium oxide), hafnium, zirconium, titanium, tantalum, aluminum, alloys of these metals, and carbides of these metals such as hafnium carbide, zirconium carbide, titanium carbide, tantalum carbide, and aluminum carbide.

Gate isolation 145 is over gate electrode 125. Isolation 145 may include a low-permittivity (“low-K”) dielectric material that separates gate electrode 125 from interconnect metallization layers, e.g., in one or more interconnect networks over and/or under structures 101, on a front- and/or back-side of substrate 199. In many embodiments, isolation 145 includes an oxide, nitride, and/or oxynitride. In some such embodiments, isolation 145 includes an oxide and/or nitride doped with carbon. Different materials in isolation 145 may perform different functions, such as providing etch selectivities. In many embodiments, isolation 145 includes an oxide and/or nitride, etc., of silicon (such as, but not limited to, SiN, SiO, SiON, SiOC, SiCN). In some embodiments, isolation 145 includes an oxide and/or nitride, as well as hydrogen (e.g., SiOCH), which may correspond to a reduced permittivity. In some embodiments, isolation 145 includes pores (e.g., nanopores) in an oxide and/or nitride, which may correspond to a reduced permittivity. Gate electrode 125 may be coupled to interconnect metallization layers by contact or via 132 through gate isolation 145.

Substrate 199 may include any suitable material or materials. Any suitable semiconductor or other material, for example, an insulator material, can be used. Substrate 199 may be any suitable substrate 199, such as a wafer, die, etc. Substrate 199 may include a semiconductor material that transistors can be formed out of and on, including a crystalline material, such as monocrystalline or polycrystalline silicon (Si), germanium (Ge), silicon germanium (SiGe), a III-V alloy material (e.g., gallium arsenide (GaAs)), a silicon carbide (SiC), a sapphire (Al₂O₃), or any combination thereof. In some embodiments, substrate 199 includes crystalline silicon and subsequent components are also silicon. In some embodiments, a crystalline material of substrate 199 is removed (e.g., by grinding) from a back-side of transistor structures 101 and replaced with an isolation material, such as that of isolation 149. Substrate 199 may be a silicon-on-insulator (SOI) substrate. Substrate 199 may also include semiconductor materials, metals, dielectrics, dopants, and other materials commonly found in IC substrates.

Shallow-trench isolation (STI) 149 is over substrate 199 and between stacks 121, for example, between subfins of substrate 199. Isolation 149 may include a low-K dielectric material, e.g., as described of isolation 145. Gate electrode 125 (for example, gate layer 123) may be on STI 149. In some embodiments, crystalline material (e.g., silicon) of substrate 199, such as in subfins, is removed beneath transistor structures 101, and material of STI 149 is on a back-side of structures 101.

FIG. 1B illustrates stack 121B of nanoribbons 122 in transistor structure 101B. Nanoribbons 122 extend in the y-directions through gate electrode 125B in the y-z plane of view B-B′ of FIG. 1B, which shows a longitudinal cross-section of nanoribbons 122. Centerlines CL_{1B}, CL_{2B}, CL_{3B} of nanoribbons 122 extend in the y-directions in the y-z plane of view B-B′ and intersect the x-z plane of view A-A′ of FIG. 1A at midpoints M_{B} of nanoribbons 122. Nanoribbon 122 (lacking an element present in the lattice of nanoribbon 120) may have a uniform thickness T₂ along a length of nanoribbon 122 (e.g., at or near midpoint M_{B} and at both ends of nanoribbons 122). In many embodiments, nanoribbon 122 has a perfectly (or very nearly perfectly) uniform thickness T₂ along the length of nanoribbon 122 between source and drain bodies 110B, and thickness T₂ is a maximum thickness T₂ of nanoribbons 122 and a minimum thickness T₂ of nanoribbons 122 (e.g., with 0.0% variation between minimum and maximum). For example, thickness T₂ of nanoribbons 122 may follow a uniform crystal lattice (e.g., of silicon under very little strain). In some embodiments, nanoribbon 122 is not perfectly uniform, but a thickness variation of thickness T₂ along the length of nanoribbon 122 between source and drain bodies 110B is less than 1% (e.g., a maximum thickness T₂ of a nanoribbon 122 is less than 1% more than a minimum thickness T₂ of the same nanoribbon 122). In many embodiments, the uniform thickness T₂ of nanoribbon 122 is approximately equal to (e.g., within 1% of) thickness T₃ at or near an end of nanoribbon 120.

FIG. 1C shows stack 121A of nanoribbons 120 in transistor structures 101A.

Nanoribbons 120 extend in the y-directions through gate electrode 125A and the y-z plane of view C-C′ of FIG. 1C, which shows a longitudinal cross-section of nanoribbons 120. Centerlines CL_{1A}, CL_{2A}, CL_{3A} of nanoribbons 120 extend in the y-directions in the y-z plane of view C-C′ and intersect the x-z plane of view A-A′ of FIG. 1A at midpoints M_{A} of nanoribbons 120. Multiple embodiments are shown in greater detail in FIGS. 1D and 1E, which magnify view 102 of FIG. 1C.

Nanoribbon 120 may include an element not present in nanoribbon 122 (e.g., an element that may be added to the lattice of nanoribbon 120 to enhance a characteristic of nanoribbon 120), and each of enhanced nanoribbons 120 may include a bulge (e.g., with a thickness T₁ at or near midpoint M_{A} of nanoribbon 120 greater than a thickness T₃ at or near an end of nanoribbon 120). Nanoribbons 120 are symmetric between bodies 110A with symmetric bulges (and thicknesses T₁, T₃). Nanoribbons 120 have thickness T₁ at midpoint M_{A} between source and drain bodies 110A, and nanoribbons 120 have thickness T₃ at an intervening point between midpoint M_{A} and one of source and drain bodies 110A (e.g., adjacent one of source and drain bodies 110A). Nanoribbons 120 may have a minimum thickness T₃ at or adjacent one of source and drain bodies 110A, and the thickness may monotonically increase from minimum thickness T₃ to maximum thickness T₁ at midpoint M_{A} between source and drain bodies 110A.

In many embodiments, thickness T₁ is at least 5% greater than thickness T₃. The bulge (e.g., thickness T₁ being greater than thickness T₃) may be caused by the enlarged lattice constant of nanoribbon 120 (e.g., with an additional element relative to nanoribbons 122), and the bulge (e.g., the difference between thicknesses T₁, T₃) may be larger for larger concentrations of the additional element in nanoribbon 120. For example, in many embodiments, a silicon germanium nanoribbon 120 with a germanium concentration greater than 20% has a thickness variation (e.g., bulge of thickness T₁ greater than thickness T₃) of at least 3% between thicknesses T₁, T₃. In many embodiments, nanoribbon 120 has a concentration of the additional element (e.g., not in nanoribbons 122) greater than 25% (e.g., 30% or 35% or 40%). In many embodiments, nanoribbon 120 has a thickness variation of more than 5% between thicknesses T₁, T₃.

In many embodiments, nanoribbon 120 has a larger thickness variation between thicknesses T₁, T₃ (e.g., of more than 5%) due to a thicker deposition of the added element on nanoribbon 120. In many embodiments, the thickness variation of nanoribbon 120 is ten times or more than more than the thickness variation of nanoribbons 122 (e.g., which may be <1%, for example, 0.1% or 0.2%). The thickness variation (e.g., bulge) of nanoribbon 120 may advantageously improve current control through nanoribbons 120. The greater thickness T₁ (relative to thickness T₃ and to other, smaller thicknesses T₁) may enable lower channel resistances (and larger “on” currents) where nanoribbon 120 is covered by gate electrode 125A. The lower thickness T₃ (where nanoribbon 120 is not covered by gate electrode 125A) may ensure lower leakage currents (e.g., lower “off” currents for a same thickness T₁). Nanoribbon 122 may have virtually no within-ribbon thickness variation (e.g., no bulge). Thickness T₂ of nanoribbon 122 may be approximately equal to (e.g., within 1% of) thickness T₃ at or near an end of nanoribbon 120.

Thickness T₁ at or near midpoint M_{A} of nanoribbon 120 may be greater than a thickness T₂ at or near midpoint M_{B} of nanoribbon 122. In some embodiments, nanoribbon 120 has a thickness T₁ at or near midpoint M_{A} 5% or more greater than thickness T₂ at or near midpoint M_{B} of nanoribbon 122, which may provide advantageous proportions of currents in transistor structures 101A, 101B. Thickness T₁ of nanoribbon 120 may be increased, e.g., by the deposition of the additive element. Thicknesses T₁, T₂ of nanoribbons 120, 122 may be controlled by independent processing of stacks 121A, 121B. Thickness T₂ at or near midpoint M_{B} of nanoribbon 122 may be greater than thickness T₁ at or near midpoint M_{A} of nanoribbon 120. Thickness T₁ (or T₂) of nanoribbon 120 (or 122) may be reduced, e.g., by a trimming of nanoribbons 120 (or 122) in stack 121A (or 121B). Either of nanoribbons 120, 122 may be 2%, 5%, 10%, 50% thicker (e.g., either of thicknesses T₁, T₂ may be greater) than the other of nanoribbons 122, 120 (and thicknesses T₂, T₁).

Bulges in nanoribbons 120 may be evidence of an element added to the now-expanded lattice between ends of nanoribbons 120 pinned to a smaller lattice constant (e.g., before expansion) at source and drain bodies 110A. The additional element (e.g., not in nanoribbons 122), even if deposited as a cladding on and around nanoribbons 120, may be evenly spread (e.g., homogenously mixed by a thorough diffusion) throughout nanoribbons 120, and the smoothness of the bulge may be due to surface tension acting to reduce surface area of the bulge and the enlarged nanoribbon 120. For example, nanoribbons 120 may have a homogenous composition along a length of nanoribbons 120 (e.g., an axis or centerline CL_{A}). In many embodiments, nanoribbons 120 have approximately equal first and second atomic compositions on each of centerlines CL_{1A}, CL_{2A}, CL_{3A} with a first atomic composition at midpoint M_{A} and a second atomic composition at an intervening point between midpoint M_{A} and one of source and drain bodies 110A (e.g., either of midpoint M₂, M₃, equidistant between midpoint M_{A} and one of source and drain bodies 110A, or the intervening point indicated as having thickness T₃, adjacent one of source and drain bodies 110A). In some embodiments, nanoribbons 120 have approximately equal first, second, and third germanium concentrations on each of centerlines CL_{1A}, CL_{2A}, CL_{3A} with a first germanium concentration at midpoint M_{A} and second and third germanium concentrations at midpoints M₂, M₃, equidistant between midpoint M_{A} and each of source and drain bodies 110A.

An additional element (e.g., not in nanoribbons 122) may be evenly spread (e.g., homogenously mixed) throughout nanoribbons 120, including vertically along a thickness T₁ or T₃ in the z-dimension. For example, nanoribbons 120 may have a homogenous composition along thickness T₁ of nanoribbons 120, e.g., with first germanium concentrations on each of midpoints M_{A} on centerlines CL_{1A}, CL_{2A}, CL_{3A} equal to (e.g., within 5% of) second germanium concentrations on surfaces of nanoribbons 120 over midpoints M_{A} (e.g., at interfaces of nanoribbons 120 and gate layer 123).

As illustrated in FIGS. 1B and 1C, nanoribbons 120, 122 couple source and drain bodies 110. In the example of FIG. 1B, NMOS nanoribbons 122 are coupled to, and in contact with, n-type source and drain bodies 110B. Source and drain bodies 110B may have any chemical composition and microstructure suitable for an NMOS transistor. N-type source and drain bodies 110B may include monocrystalline or polycrystalline semiconductor material. In many embodiments, n-type source and drain bodies 110B include a Group IV or III-V semiconductor material doped with any impurity dopants known to be suitable for the desired conductivity type, and to any concentration known to be suitable for transistors. In some embodiments, bodies 110B include silicon and an n-type dopant, such as phosphorous, arsenic, or another donor impurity.

In the example of FIG. 1C, PMOS nanoribbons 120 are coupled to, and in contact with, p-type source and drain bodies 110A. P-type source and drain bodies 110A may have any chemical composition and microstructure suitable for a PMOS transistor. Source and drain bodies 110A may include monocrystalline or polycrystalline semiconductor material. In many embodiments, source and drain bodies 110A include a Group IV or III-V semiconductor material doped with any impurity dopants known to be suitable for the desired conductivity type, and to any concentration known to be suitable for transistors. In some embodiments, bodies 110A include silicon, germanium, and a p-type dopant, such as boron, aluminum, gallium or any other acceptor impurity. In some exemplary embodiments, source and drain bodies 110B are predominantly silicon doped with any suitable concentration of donor impurities while source and drain bodies 110A are predominantly silicon germanium doped with any suitable concentration of acceptor impurities.

Source and drain bodies 110 may include (or contact) interface layers 112. Buffer layers 112 contact ends of nanoribbons 120, 122 (e.g., covering an entire x-z end of nanoribbons 120, 122). Layers 112 may be thin layers 112, for example, epitaxially grown on nanoribbons 120 only as thick as necessary to serve as a growth template (e.g., nucleation layer 112) for the growth of source and drain bodies 110. Interface layers 112 in or on bodies 110A, 110B may have a lower dopant concentration than the bodies 110 layers 112 are in or on (including a dopant concentration of zero in layer 112). Interface layers 112 in or on bodies 110A may have a concentration of the additional (enhancing) element less than the concentration of the additional element in nanoribbons 120. In some embodiments, interface layers 112 in or on bodies 110A has a concentration of the additional element less than the concentration of the additional element in portions of bodies 110A contacting layers 112. For example, in some such embodiments, layer 112 has a concentration of germanium (e.g., <20%) less than a concentration of germanium in silicon germanium source or drain body 110A contacting (e.g., epitaxially grown from) layer 112 and less than a concentration of germanium in silicon germanium nanoribbons 120 contacting layer 112. In some such embodiments, layer 112 has a dopant concentration (e.g., of boron) less than a dopant concentration of the source or drain body 110A contacting (e.g., epitaxially grown from) layer 112. In some embodiments, layers 112 on nanoribbons 122 have a dopant concentration (e.g., of phosphorous) less than a dopant concentration of the source or drain body 110B contacting (e.g., epitaxially grown from) layer 112. Interface layer 112 may be a high-quality (e.g., epitaxially grown) layer 112 that inhibits diffusion (e.g., of dopants) into nanoribbons 120, 122. Layer 112 may inhibit diffusion during processing (e.g., a high-temperature anneal) due to the composition of layer 112 (e.g., a concentration as described above).

Device 100 includes spacers 142, 143 between source and drain bodies 110, between gate electrode 125 and source and drain bodies 110, and between gate electrode 125 and metallization structures 131, e.g., as electrical insulation. Gate electrode 125 is between spacers 142, 143. Cavity spacers 142 are between nanoribbons 120, 122. Spacers 143 are over an uppermost of nanoribbons 120, 122. Nanoribbons 120, 122 extend through spacers 142, 143. Spacers 142, 143 may have any suitable composition, for example, any suitably insulative (e.g., electrically insulative) composition. Advantageously, spacers 142, 143 include one or more low-K materials, e.g., as described of isolation 145 at FIG. 1A. For example, each of spacers 142, 143 may include an oxide, nitride, and/or oxynitride (such as of silicon), with or without carbon doping or hydrogen, and with or without nanopores.

Trench isolation 141 is over and/or under source and drain bodies 110. Isolation 141 may include a low-K dielectric material that separates bodies 110 from interconnect metallization layers (e.g., in one or more interconnect networks), over and/or under structures 101. Isolation 141, 145, 149 (and spacers 142, 143) may have the same or differing compositions.

Transistor structures 101 may be coupled to interconnect metallization layers by metallization structures 131, which are contact structures on source and drain bodies 110. In some embodiments, IC device 100 includes front- and back-side interconnect networks, and structures 101 are coupled to metallization layers by in one or more interconnect networks by front- or back-side metallization structures 131. Structures 131 may be coupled to interconnect layers by vias contacting structures 131.

FIG. 1D illustrates view 102 from FIG. 1C in greater detail. Thickness T₁ of nanoribbon 120 is through midpoint M_{A} on centerline CL_{2A}. Midpoints M₂, M₃ are on centerline CL_{2A}, each equidistant between midpoint M_{A} and one of source and drain bodies 110A. Surfaces S₁, S₂ are interfaces of nanoribbon 120 and gate layer 123, over and under, respectively, midpoint M_{A}. Interface layers 112 are on ends of nanoribbon 120, in or on bodies 110A (e.g., as nucleation layers 112 for growth of source and drain bodies 110A off of ends of nanoribbon 120).

Nanoribbon 120 may have a bulge (e.g., thickness T₁ being greater than thickness T₃) caused by an enlarged lattice constant of nanoribbon 120 (e.g., with an additional element relative to nanoribbons 122). Nanoribbons 120 may have a minimum thickness T₃ at or adjacent one of source and drain bodies 110A, and the thickness of nanoribbon 120 may monotonically increase from minimum thickness T₃ to maximum thickness T₁ at midpoint M_{A} between source and drain bodies 110A.

Nanoribbon 120 may have a homogenous composition along thickness T₁ of nanoribbons 120, e.g., with a first atomic composition (and, e.g., first germanium concentration) on midpoint M_{A} on centerline CL_{2A} equal to (e.g., within 5% of) a second atomic composition (and, e.g., germanium concentration) on surface S₁ of nanoribbon 120 over midpoint M_{A}. In many embodiments, nanoribbon 120 has a first atomic composition (and, e.g., first germanium concentration) on midpoint M_{A} on centerline CL_{2A} equal to (e.g., within 5% of) a third atomic composition (and, e.g., germanium concentration) on surface S₂ of nanoribbon 120 under midpoint M_{A}. In many embodiments, nanoribbon 120 has a same composition (e.g., germanium concentration) along thickness T₁ at midpoint M_{A} on centerline CL_{2A} and on surfaces S₁, S₂ over and under midpoint M_{A}. In some embodiments, nanoribbons 120 have approximately equal first, second, and third atomic compositions on centerline CL_{2A} with a first atomic composition (and, e.g., first germanium concentration) at midpoint M_{A} and second and third atomic compositions (and, e.g., germanium concentrations) at midpoints M₂, M₃, equidistant between midpoint M_{A} and each of source and drain bodies 110A.

FIG. 1E shows embodiments of magnified view 102. In some embodiments, nanoribbons 120 have minimum thicknesses T₄ between midpoints M₂, M₃ and thicknesses T₃ on or adjacent bodies 110A. In some such embodiments, nanoribbons 120 have a minimum thickness T₄, and the thickness monotonically increases from minimum thickness T₄ to maximum thickness T₁ at midpoint M_{A} between source and drain bodies 110A. In some embodiments, minimum thicknesses T₄ are in outer quarters of nanoribbons 120, e.g., between bodies 110A and midpoints M₂, M₃ (which may be equidistant between midpoint M_{A} and bodies 110A). In some such embodiments, minimum thicknesses T₄ are in outer tenths of nanoribbons 120 (e.g., nearer bodies 110A).

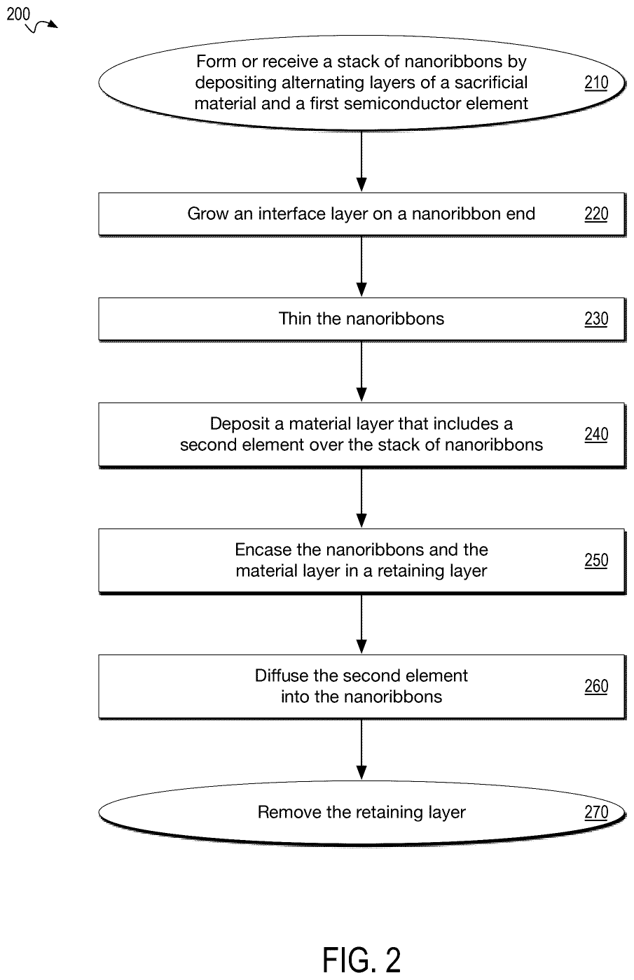

FIG. 2 is a flow chart of methods 200 for forming a nanoribbon with an element added to and interspersed in the nanoribbon lattice, in accordance with some embodiments. Methods 200 may be utilized to add atoms of at least one element into a nanoribbon of another element while also retaining nanoribbons of the other element, e.g., for complementary applications. Methods 200 include operations 210-270. Some operations shown in FIG. 2 are optional. Additional operations may be included. FIG. 2 shows an example sequence, but the operations can be done in other orders as well, and some operations may be omitted. Some operations can also be performed multiple times before other operations are performed. For example, multiple nanoribbons (and stacks of nanoribbons) may be formed and thinned before an additive element is deposited on the nanoribbons. Some operations may be included within other operations so that the number of operations illustrated FIG. 2 is not a limitation of the methods 200.

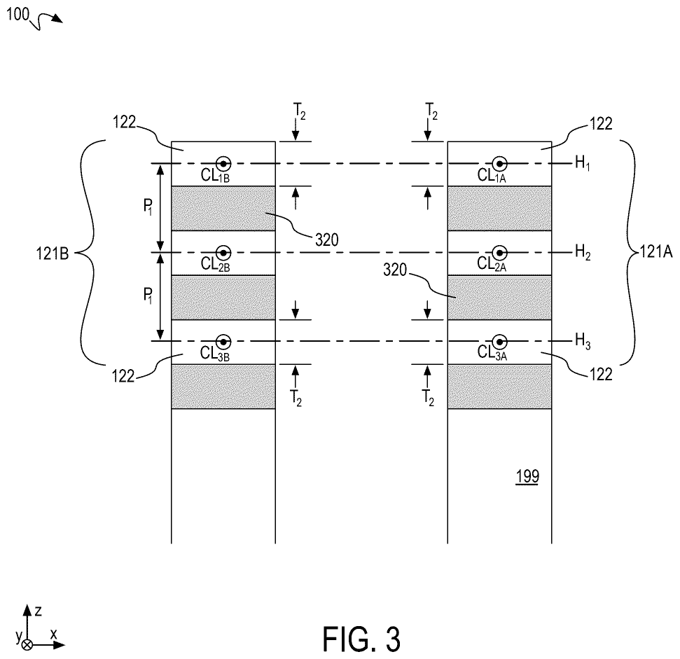

FIGS. 3, 4, 5, 6, 7, 8, and 9 illustrate cross-sectional profile views of nanoribbons 120 having an added element diffused into the crystal lattices, at various stages of manufacture, in accordance with some embodiments. FIGS. 3-9 show possible examples of intermediate structures during an embodiment of a practice of methods 200 of FIG. 2.

Returning to FIG. 2, methods 200 begin at operation 210 with forming or receiving a stack of material layers. The stack of material layers may be (or may be formed into) a stack of nanoribbons. The nanoribbons may each be more narrow than tall (e.g., nanowires) or much wider (e.g., nanosheets). In many embodiments, a stack of nanoribbons is formed by depositing alternating material layers in a stack, e.g., alternating layers of a crystalline (e.g., semiconducting) material and of a sacrificial material. The sacrificial material may be a semiconductor material. In some embodiments, the semiconducting and sacrificial materials share one or more constituent elements. For example, in some embodiments, the sacrificial material is silicon germanium, and the semiconducting material is pure (or predominantly) silicon (e.g., without germanium present). Any suitable materials may be employed, such as materials that may be semiconductors (e.g., enhanced) with the addition of one or more elements diffused into the crystalline lattice. Although the examples of silicon and germanium may be provided, the nanoribbons may be enhanced to include III-V materials, II-VI materials, and other semiconducting materials.

Methods 200 enable the use of preexisting processes (for example, leveraging existing infrastructure and proven, e.g., reliable, flows) to form nanoribbons (for example, without modifying a stack of material layers) before at least some nanoribbons are enhanced by the addition of an element. For example, silicon nanoribbons may be formed by a proven process, and some of the silicon nanoribbons may then be converted to silicon germanium nanoribbons, e.g., for NMOS and PMOS transistors, respectively. In many embodiments, silicon nanoribbons are fabricated using a conventional flow, and silicon germanium nanoribbons are fabricated using methods 200 to produce complementary transistors of the same size and with nanoribbon channels at same heights and with same pitches. Accordingly, benefits (e.g., flow and tool re-use) may be accrued from preserving a material stack (including layer thicknesses). However, the material stack (e.g., one or more layer thicknesses) may be altered from conventional flows as is necessary or convenient. In some embodiments, the thickness of a semiconductor material layer is reduced to standardize an eventual, resultant thickness of the enhanced semiconductor layer (e.g., nanoribbon) following a performance of methods 200. In some such embodiments, the semiconductor layer thickness is reduced in some regions of a received substrate and is not reduced in other regions.

Methods 200 (e.g., processing or forming the stack of material layers at operation 210) may include cutting (e.g., etching) into nanoribbons by any suitable means, for example, photolithographic means. A wide-area stack of material layers may be separated by etches into multiple fins of layers (e.g., nanoribbons). Thin fins (e.g., from tightly spaced etches) may be formed into nanowires, and wide fins (e.g., from loosely spaced etches) may be formed into nanosheets. In many embodiments, sacrificial or dummy gates are deposited over fins of material layers, a spacer dielectric is conformally deposited over the fins and dummy gates, and the fins are cut into nanoribbon segments by etches between the spacer sidewalls on the dummy gates

FIG. 3 illustrates workpiece or IC device 100 having material layers or nanoribbons 122 in alternating stacks 121 with sacrificial material layers 320, in accordance with some embodiments, for example, following or during a performance of operation 210. Stacks 121A, 121B are identical in the example of FIG. 3, but may be separately processed by methods 200. Identical stacks 121A, 121B include material layers or nanoribbons 122 and sacrificial material layers 320. In both stacks 121A, 121B, pitches P₁ are between layers or nanoribbons 122, which have thicknesses T₂. Layers or nanoribbons 122 in stacks 121A, 121B have coplanar centerlines CL at heights H₁, H₂, H₃. Material layers or nanoribbons 122 have a crystalline lattice, e.g., of silicon or another semiconductor material. Sacrificial layers 320 include a material having an etch selectivity with layers or nanoribbons 122. In many embodiments, stacks 121 are over a substrate 199 (e.g., subfins) including a material having an etch selectivity with sacrificial layers 320, such as the material of layers or nanoribbons 122. In many embodiments, nanoribbons 122 (and much of substrate 199) are pure silicon, and layers 320 are silicon germanium. Any suitable material may be deployed.

Methods 200 (e.g., processing or forming the stack of material layers at operation 210) may include further processing of the stack of layers or nanoribbons as necessary. A recess or dimple etch may remove exposed portions of the sacrificial layers between the crystalline (e.g., semiconductor) material layers, and another spacer dielectric may be deposited in the resultant cavities. Source and drain regions may be epitaxially grown from exposed ends of the nanoribbons (e.g., extending between the spacer dielectrics).

Methods 200 continue with optionally growing an interface layer on an end of a nanoribbon at operation 220 of FIG. 2. The interface layer may serve as either or both of a nucleation layer for epitaxially growing source and drain bodies at ends of nanoribbon channels and a diffusion barrier for inhibiting diffusion between nanoribbon channels and source and drain bodies. In some embodiments, the interface layer is epitaxially grown on one or more ends of one or more nanoribbons. In some such embodiments, the source and drain bodies are epitaxially grown from the interface layers. Interface layers may be grown on both nanoribbons to be enhanced with a diffused element and nanoribbons to be retained without the added element. The interface layers and source and drain bodies may include any suitable materials (e.g., as described at least at FIGS. 1B and 1C). The interface layers and source and drain bodies may be grown by any suitable means, for example, epitaxially by an atomic layer deposition (ALD). Advantageously, the interface layers in particular are grown free of defects, which may aid in the inhibition of diffusion.

During methods 200 (e.g., at operation 260), diffusion into and out of longitudinal nanoribbon surfaces may be promoted, for example, by a high-temperature anneal. However, diffusion (e.g., of dopants from the source and drain bodies) through the nanoribbon ends may be undesired. The interface layer may provide a diffusion barrier to prevent (or at least inhibit) diffusion between nanoribbon channels and source and drain bodies. The interface layer may have a high-quality lattice grown without dopants (or with a lower dopant concentration than the source and drain bodies) and without the element to be added to at least some nanoribbons (or with a lower concentration than is to be in the enhanced nanoribbons). For example, interface layers may be grown on ends of silicon nanoribbons in multiple stacks, some stacks to be enhanced with the addition of germanium and some stacks to be maintained as pure silicon. Doped-silicon source and drain bodies may be epitaxially grown from undoped silicon interface layers epitaxially grown from ends of maintained silicon nanoribbons. In the same embodiment (e.g., device or workpiece), doped-silicon germanium source and drain bodies may be epitaxially grown from undoped silicon germanium interface layers epitaxially grown from ends of to-be-enhanced silicon nanoribbons. The undoped silicon germanium interface layers may have a lower concentration of germanium than the silicon germanium source and drain bodies and a lower concentration of germanium than the eventual silicon germanium nanoribbons (e.g., those silicon nanoribbons that are coupled with the interface layers and that are to be enhanced with germanium).

Methods 200 may include further processing, which may employ conventional (e.g., existing) processes. For example, the sacrificial layers may be removed from the stack of alternating material layers, e.g., following a covering with dielectric of epitaxial bodies in source-drain trenches between dummy gates. The dummy gates may be removed and the nanoribbons exposed by removal of the sacrificial layers between the nanoribbons and between spacer dielectrics.

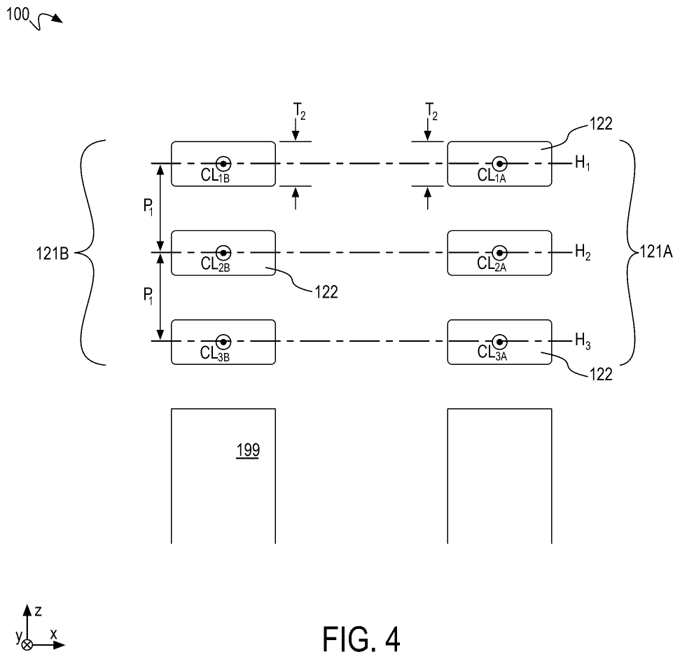

FIG. 4 illustrates workpiece or device 100 having stacks 121 with released nanoribbons 122 (e.g., with sacrificial material absent between nanoribbons 122), in accordance with some embodiments, for example, following a performance of operations 210 and/or 220. Nanoribbons 122 may be coupled with source and drain epitaxial bodies, e.g., in front of and behind the viewing plane of FIG. 4, which may promote strain of enhanced nanoribbon lattices following the addition of a diffused element. The removal of sacrificial material and release of nanoribbons 122 provides space for further operations of methods 200 and the growth (e.g., bulging) of lattices of selected nanoribbons 122.

Methods 200 may add an element to some or all of layers or nanoribbons 122, e.g., to improve performance and reliability of nanoribbons 122. In some embodiments, an element (e.g., a semiconductor element) is diffused into some of layers or nanoribbons 122 for a first type (e.g., n- or p-type) of transistors, and others of layers or nanoribbons 122 are retained for a second (e.g., complementary) type of transistors (e.g., in stack 121B). In some such embodiments, silicon nanoribbons 122 in stack 121A are converted into silicon germanium channels (e.g., in PMOS transistors), and silicon nanoribbons 122 in stack 121B are maintained as silicon channels (e.g., in NMOS transistors).

Methods 200 continue with optionally thinning at least some of the nanoribbons at operation 230 of FIG. 2. Nanoribbons to be enhanced with an added element will increase in size due to the addition and may be pre-thinned to control a final thickness. The nanoribbons may be thinned by any suitable means, e.g., by a selective plasma etch. In many embodiments, the nanoribbons are thinned by isotropically removing material from exposed surfaces of the nanoribbons. In some such embodiments, the nanoribbons are predominantly silicon, and (e.g., an outer layer of) silicon is removed isotropically from all exposed nanoribbon surfaces. In many embodiments, the nanoribbons to be enhanced are isotropically thinned, and the nanoribbons to be maintained (e.g., with an unchanged composition) are masked off or over to prevent undesired thinning. For example, stacks of nanoribbons to be remain unchanged may be masked off from adjacent stacks of nanoribbons to be enhanced.

The to-be-enhanced nanoribbons may be thinned to any suitable thickness. An additive element will be deposited in a material layer over a stack of nanoribbons (e.g., at operation 240 of methods 200), and the added element will be diffused into the nanoribbon lattice (e.g., at operation 260 of methods 200). The final concentration of the added element in an enhanced nanoribbon is influenced by a number of variables, such as the initial concentration of the added element in the initial nanoribbon (e.g., zero), the size (e.g., volume) of the initial nanoribbon, the initial concentration of the added element in the deposited material layer, and the size (e.g., thickness) of the deposited material layer. The final concentration of the added element can be increased by depositing a thicker material layer or a material layer with a higher concentration of the added element, but the final concentration of the added element in the enhanced nanoribbon is limited by the size of the initial nanoribbon. The smaller (e.g., thinner) the initial nanoribbon is, the more the final concentration of the added element in the enhanced nanoribbon can be influenced with the deposited material layer.

In some embodiments, the nanoribbons are thinned to approximately 2 nm (e.g., between 1.5 and 2.5 nm), which may enable higher final concentrations of an added element in enhanced nanoribbons, particularly thin nanoribbons. Thick final nanoribbons and final nanoribbons with lower allowed final concentrations of the added element may permit larger initial (thinned) thicknesses. Isotropic (e.g., balanced) removal of material from exposed surfaces (e.g., upper and lower surfaces) of the to-be-enhanced nanoribbons ensures that nanoribbon centerlines may be kept at same heights in enhanced and unchanged stacks.

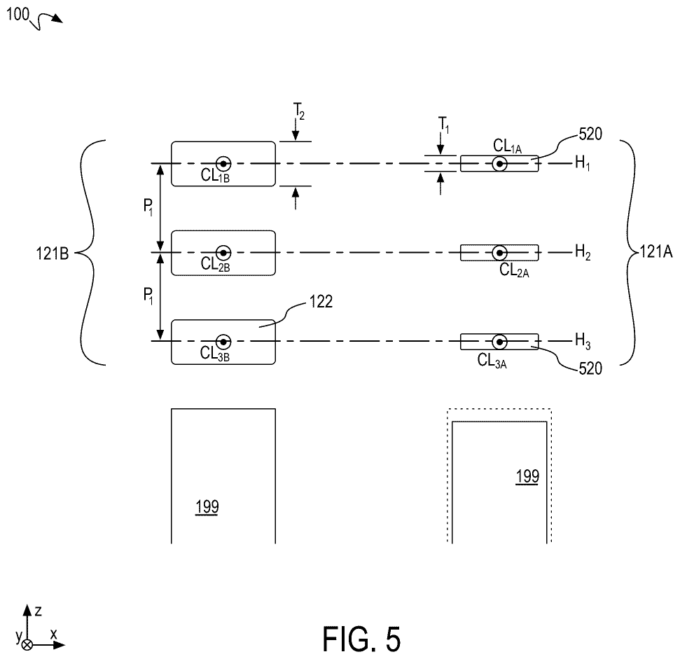

FIG. 5 illustrates workpiece or device 100 having adjacent stacks 121B, 121A of standard and thinned nanoribbons 122, 520, in accordance with some embodiments, for example, following a performance of operation 230. Thinned nanoribbons 520 are prepared for further enhancement processing (such as the deposition and diffusion of an added, second element).

Thinned nanoribbons 520 are at the same heights H₁, H₂, H₃ as before thinning operation 230. Thinned nanoribbons 520 and centerlines CL_{1A}, CL_{2A}, CL_{3A} are at same heights H₁, H₂, H₃ as centerlines CL_{1B}, CL_{2B}, CL_{3B} of standard nanoribbons 122. In some embodiments, material is isotropically removed from exposed surfaces of substrate 199 (e.g., of subfins). In many embodiments, surfaces of substrate 199 below nanoribbons 122, 520 are masked (e.g., not exposed). In many embodiments, stack 121B is covered by a mask material (not shown), e.g., to segregate stack 121B of nanoribbons 122 from stack 121A of nanoribbons 520 during processing (such as thinning) of nanoribbons 520.

Returning to FIG. 2, methods 200 continue at operation 240 with depositing a material layer over a stack of nanoribbons. Any suitable material(s) may be deposited in one or more layers over the stack of nanoribbons, and any suitable means may be employed to deposit the layer(s). In many embodiments, the nanoribbons include a first element, and the deposited material layer includes a second element. Methods 200 may add a second element (such as germanium) to nanoribbons entirely (i.e., purely) of a first element (such as silicon), but methods 200 may also be used to add more of a second element (e.g., to increase a concentration of the second element) to nanoribbons of (at least) the first and second elements. The first and second elements may both be semiconductor elements (such as silicon and germanium), but, even though the compound or alloy formed by the first and second elements may be a semiconductor material, the first and second elements need not both be semiconductor elements. The deposited material layer may include elements besides the second element (e.g., to be added to the lattice of the first element). In many embodiments, the deposited material layer includes the first and second elements. For example, a material layer of silicon germanium may be deposited on nanoribbons of predominantly silicon.

In many embodiments, the material layer is deposited conformally over individual ones of the nanoribbons. In many embodiments, the material layer is deposited epitaxially, e.g., by an ALD, which allows for great control of the thickness of the deposited material layer, and so for great control of the final concentration of the added element in the enhanced nanoribbon. Epitaxial deposition by ALD may ensure a high-quality lattice is deposited on the nanoribbon, which may improve subsequent diffusion of the additive, second element into (and of the first element out of) the nanoribbon. Epitaxial deposition by ALD may also enable selective deposition of the additive, second element onto the nanoribbon.

As described elsewhere herein (e.g., at least at operation 230 of methods 200), the final concentration of the added element can be increased by depositing a thicker material layer and/or a material layer with a higher concentration of the added element. When increasing the final (resultant) concentration of the added element by depositing a material layer, the final concentration of the added element is limited by (e.g., capped below) the concentration of the added element in the deposited material layer. While adding a thicker, higher-concentration layer may be desired to most-efficiently maximize a resultant concentration of the nanoribbon, a lattice mismatch between the nanoribbon and the deposited material layer may limit the thickness (and/or concentration) of the deposited material layer to below a critical thickness (e.g., to prevent dislocation defects). In many embodiments, the material layer is deposited over the stack of nanoribbons to a thickness of at least 1 nm, preferably to 1.5 nm or more, which may correspond to a sufficient concentration of the added element in the final nanoribbon.

Various constraints may impose deposited material layer thickness maximums. In many embodiments, the material layer is deposited over the stack of nanoribbons to a thickness of 3 nm or less, which may provide more of the added element while maintaining margin below a critical thickness to prevent dislocation defects. For embodiments having nanoribbons trimmed to approximate thicknesses of 2 nm, the material layer is deposited over the stack of nanoribbons to a thickness greater than or equal to half of a thickness of the nanoribbons and less than or equal to one-and-a-half times the thickness of the nanoribbons. While thicker (e.g., lower-concentration) material layers may be deposited, space may be limited between nanoribbons (e.g., for satisfactory deposition of both material layers and both subsequent retaining layers). Space between nanoribbons may also be limited by the need for space for eventual gate electrode materials. Limiting a deposited material layer thickness may also prevent the need for (and be less expensive than) thinning enhanced nanoribbons after fabrication.

In many embodiments, a material layer of silicon germanium is epitaxially and conformally deposited over initial nanoribbons of predominantly silicon. In many embodiments, the material layer is deposited over the stack of nanoribbons to an atomic composition including at least 20% germanium. Advantageously, an enhanced, silicon germanium nanoribbon has a germanium concentration of at least 20% (e.g., for increased strain and improved performance and reliability), so higher deposited concentrations may be preferred. In many embodiments, a material layer having a germanium concentration of 65% (or less) is deposited over silicon nanoribbons, which may provide more germanium (e.g., in less space) while maintaining margin below a critical thickness.

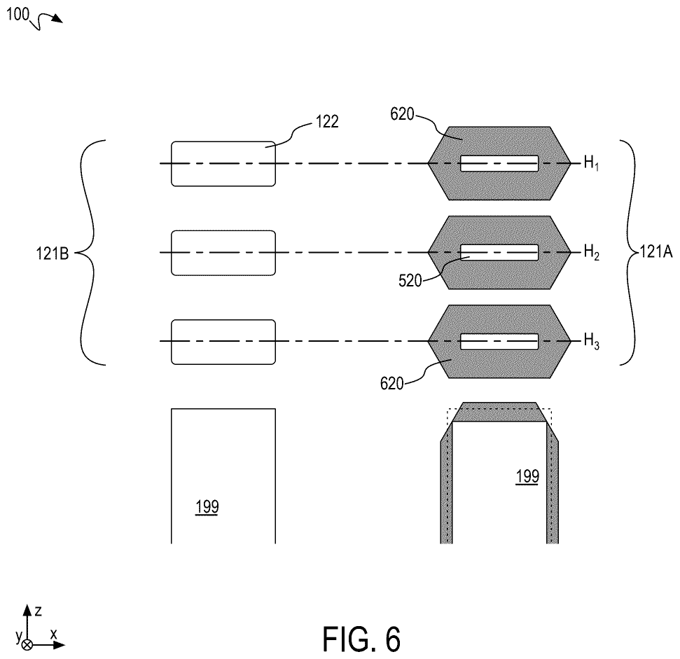

FIG. 6 illustrates a workpiece or IC device 100 having a material layer 620 deposited on and around stack 121A of thinned nanoribbons 520, in accordance with some embodiments, for example, following a performance of depositing operation 240. Material layer 620 over nanoribbons 520 may have faceted surfaces. Stack 121B of conventional nanoribbons 122 is maintained, e.g., at heights H₁, H₂, H₃ and without material layer 620.

Material layers 620 have a higher concentration than the eventual, resultant concentration of the eventual, resultant structures (e.g., enhanced nanoribbons) will be following an intermixing (e.g., diffusion) with the existing, thinned nanoribbons 520. As the concentration of nanoribbons 520 prior to diffusion of the second, added element into nanoribbons 520 may be low (e.g., zero), the total bulk of a single nanoribbon 520 and a corresponding material layer 620 may have a greater thickness than the eventual, resultant structure (e.g., enhanced nanoribbon).

Returning to FIG. 2, methods 200 continue with encasing the nanoribbons and the material layer in a retaining layer at operation 250. The retaining layer may be any suitable material(s) and may encase the nanoribbons and material layer by any suitable means. The encapsulation of the retaining layer may be necessary to contain lattice materials during a high-temperature diffusion, e.g., lattice materials that might otherwise precipitate and agglomerate at an external nanoribbon surface. In some embodiments, the retaining layer is deposited to a thickness of 0.5 nm or more, which may be a sufficient thickness to retain the nanoribbon materials and the deposited material layer during diffusion. In some embodiments, the retaining layer is deposited to a thickness of 2 nm or less, which may be a sufficient thickness to ensure retention of the nanoribbon materials and the deposited material layer (e.g., even during a longer or higher-temperature diffusion), but to also provide sufficient clearance for material deposition and removal. In many embodiments, the nanoribbons and material layer are encased in the retaining layer by conformally depositing the retaining layer around each of the nanoribbons. In many embodiments, the retaining layer is epitaxially deposited (e.g., by ALD) as a high-quality, low-defect crystalline layer.

In many embodiments, the retaining layer is a dielectric layer. In many embodiments, the retaining layer is (or includes) an oxide or a nitride, which may provide lattice vacancies for assisting (e.g., enhancing) diffusion. In some embodiments, the retaining layer is deposited over a passivation layer (e.g., of a native oxide) is formed on the nanoribbons, which may also provide diffusion-assisting vacancies. The retaining layer may also enhance diffusion by providing compressive (or tensile) stress on the deposited material layer and nanoribbon. In some embodiments, the retaining layer is silicon nitride (e.g., an epitaxially and conformally deposited, high-quality, low-defect crystalline layer of silicon and nitrogen). A retaining layer of silicon nitride may advantageously provide both strain (e.g., from up to 3 GPa of compressive or tensile stress) and vacancies of oxygen and/or nitrogen for subsequent diffusion. Strain- and vacancy-assisted diffusion of the nanoribbon materials and the deposited material layer (e.g., while retained in a layer of silicon nitride) may enable a reduced diffusion temperature or duration, which may provide margin to thermal-budget requirements.

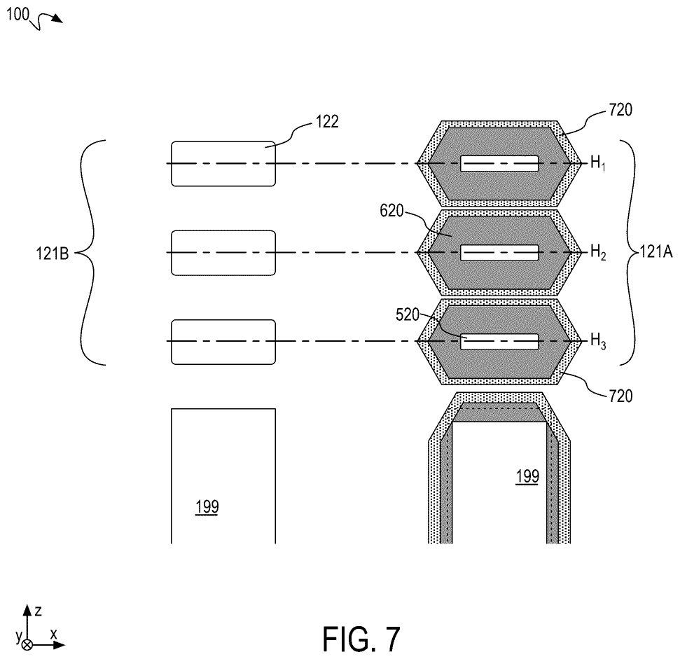

FIG. 7 illustrates a workpiece or IC device 100 having retaining layers 720 conformally encasing thinned nanoribbons 520 and material layers 620, in accordance with some embodiments, for example, following a performance of encasing operation 250. Retaining layers 720 are conformally on and around material layers 620. Layers 720 have sufficient thickness to contain lattice materials of nanoribbons 520 and layers 620 while still allowing for clearance between layers 720 (around adjacent nanoribbons 520).

Returning to FIG. 2, methods 200 continue with diffusing the second element into the nanoribbons at operation 260. The second element may be an added element that diffuses into the nanoribbons from the deposited material layer. The first element in the nanoribbons concurrently diffuses from the nanoribbons into the deposited material layer such that the first and second elements intermix in the combined nanoribbon-deposited layer structure. The diffusion may be performed to a satisfactory mixing (e.g., a thorough evening out of the concentrations and elimination of any concentration gradient), for example, by diffusing for a sufficiently long duration, at a sufficiently high temperature, etc. For example, germanium may diffuse from a conformally deposited layer of silicon germanium into a silicon nanoribbon, and silicon may diffuse from the nanoribbon outward, until the silicon and germanium are thoroughly intermixed (e.g., into a thickened nanoribbon with no discernible border between the thinned nanoribbon and deposited layer). As described (at least at operation 250), strain and vacancies provided by the retaining layer may reduce a required diffusion temperature (e.g., to a few hundred degrees) and/or duration (e.g., to a few minutes or less than a minute) and provide margin to thermal-budget requirements.

As described (e.g., at operation 220 of methods 200 and of layer 112 at FIGS. 1B and 1C), an interface layer may inhibit undesired diffusion into a nanoribbon channel (e.g., from source and drain epi), which may affect or be affected by thermal-budget requirements. For example, after the second element is diffused into the nanoribbons, the interface layer has a concentration of the second element less than both a concentration of the second element in the source or drain body (e.g., epitaxially grown from the interface layer) and a concentration of the second element in the nanoribbons, which may provide a buffer to (and inhibit) diffusion through the nanoribbon ends.

The second, added element may be diffused into the nanoribbons by any suitable means, for example, a rapid thermal anneal (RTA), such as a plasma anneal at a low partial pressure of oxygen. Other convenient means may be employed.

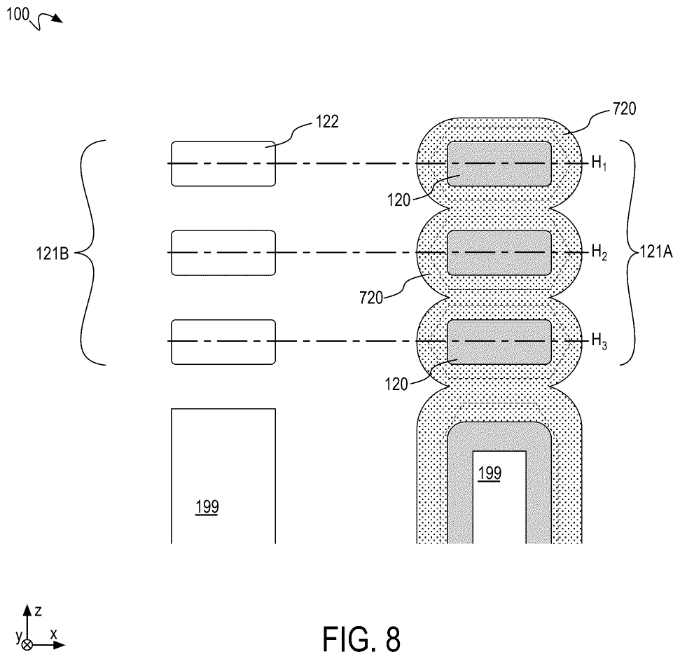

FIG. 8 illustrates a workpiece or IC device 100 having stack 121A of enhanced nanoribbons 120 adjacent stack 121B of conventional nanoribbons 122, in accordance with some embodiments, for example, following a performance of diffusing operation 260. Enhanced nanoribbons 120 are larger than the initially thinned nanoribbons, but may have a smaller extent than with the deposited material layer, e.g., due to the diffusion.

Retaining layer 720 may be degraded (e.g., less pure and with a defective lattice) following the diffusion. In many embodiments, layer 720 (initially including a high-quality silicon nitride) has an irregular lattice of silicon, nitrogen, and germanium.

Returning to FIG. 2, methods 200 continue at operation 270 with removing some or all of the retaining layer around the nanoribbons. In many embodiments, removing the retaining layer provides space for a gate electrode (e.g., a higher-K gate dielectric and workfunction metals) between the nanoribbons. The retaining layer may be removed by any suitable means, e.g., a selective, dry etch.

In some embodiments, the enhanced nanoribbons are trimmed to a desired thickness. Advantageously, enhanced nanoribbons do not require a further trimming operation following diffusion.

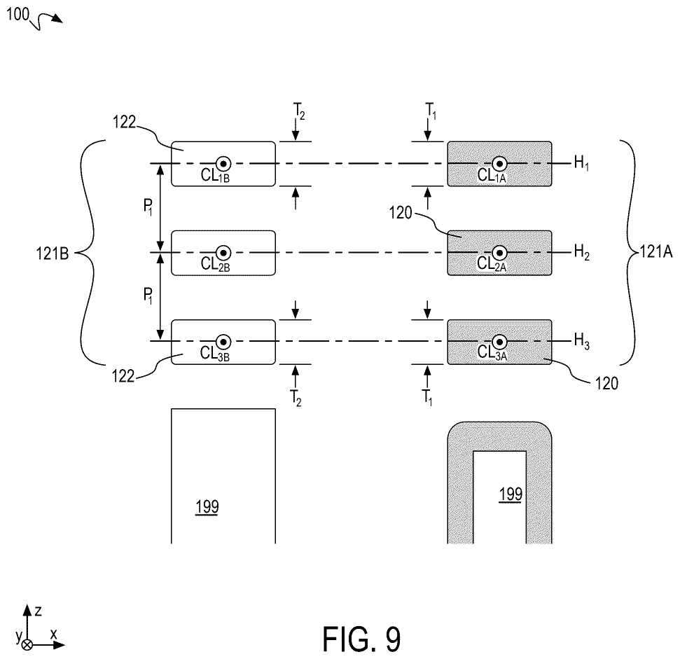

FIG. 9 illustrates a workpiece or IC device 100 having adjacent stacks 121 of enhanced and conventional nanoribbons 120, 122, respectively, in accordance with some embodiments, for example, following a performance of removing operation 270. The retaining layer is absent around nanoribbons 120.

Enhanced nanoribbons 120 in stack 121A have thickness T₁ at their midpoints (e.g., on centerlines CL_{1A}, CL_{2A}, CL_{3A}) and include an added element relative to nanoribbons 122. Conventional nanoribbons 122 in stack 121B have a smaller thickness T₂ (relative to thickness T₁) at their midpoints (e.g., on centerlines CL_{1B}, CL_{2B}, CL_{3B}) and the added element is not present in nanoribbons 122. Nanoribbons 120, 122 have a same pitch P₁ and are centered on the same heights H₁, H₂, H₃.

Further processing (such as conformal deposition of a gate dielectric layer and workfunction metal(s), etc.) may be performed to form transistor structures with nanoribbons 120, 122 as channels (e.g., as described at least at FIGS. 1A-1E).

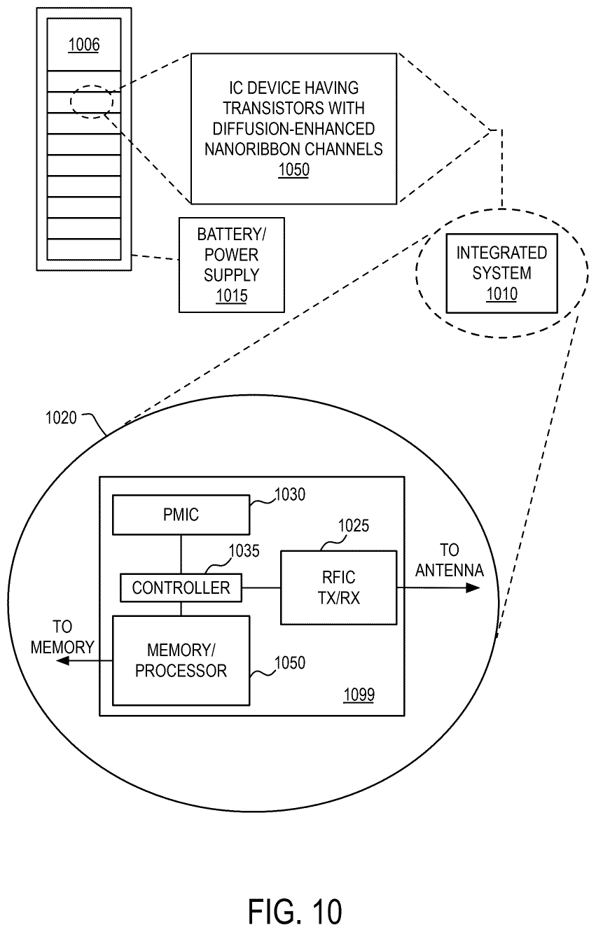

FIG. 10 illustrates a diagram of an example data server machine 1006 employing an IC device having diffusion-enhanced nanoribbon channels, in accordance with some embodiments. Server machine 1006 may be any commercial server, for example, including any number of high-performance computing platforms disposed within a rack and networked together for electronic data processing, which in the exemplary embodiment includes one or more devices 1050 having diffusion-enhanced nanoribbon channels.

Also as shown, server machine 1006 includes a battery and/or power supply 1015 to provide power to devices 1050, and to provide, in some embodiments, power delivery functions such as power regulation. Devices 1050 may be deployed as part of a package-level integrated system 1010. Integrated system 1010 is further illustrated in the expanded view 1020. In the exemplary embodiment, devices 1050 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 1050 is a microprocessor including a static RAM (SRAM) cache memory. As shown, device 1050 may be an IC device having diffusion-enhanced nanoribbon channels, as discussed herein. Device 1050 may be further coupled to (e.g., communicatively coupled to) a board, an interposer, or a substrate 1099 along with, one or more of a power management IC (PMIC) 1030, RF (wireless) IC (RFIC) 1025 including a wideband RF (wireless) transmitter and/or receiver (TX/RX) (e.g., including a digital baseband and an analog front end module further includes a power amplifier on a transmit path and a low noise amplifier on a receive path), and a controller 1035 thereof. In some embodiments, RFIC 1025, PMIC 1030, controller 1035, and device 1050 include having diffusion-enhanced nanoribbon channels.

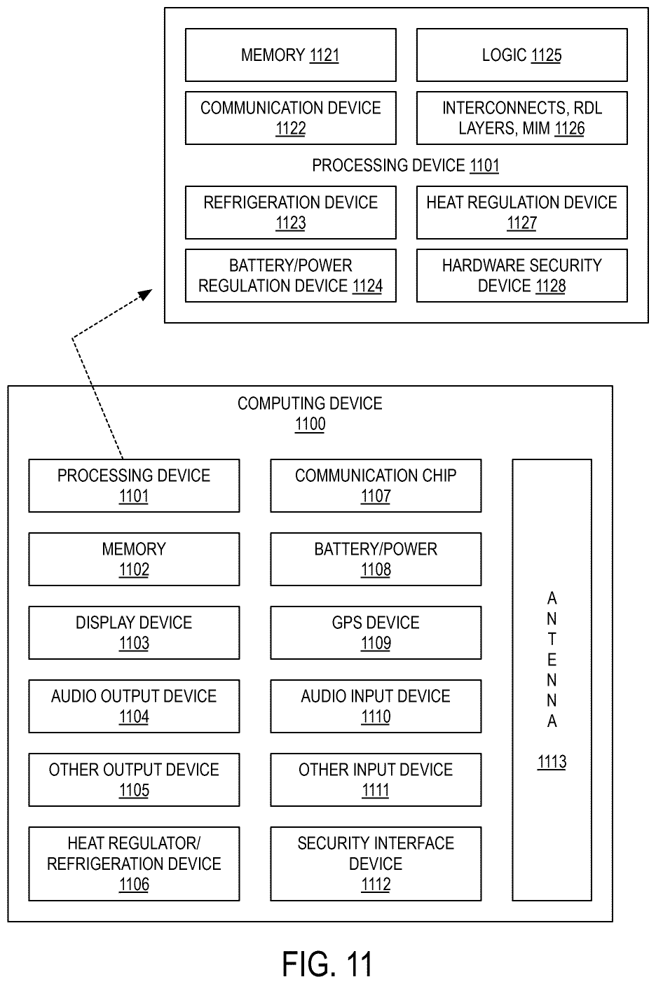

FIG. 11 is a block diagram of an example computing device 1100, in accordance with some embodiments. For example, one or more components of computing device 1100 may include any of the devices or structures discussed herein. A number of components are illustrated in FIG. 11 as being included in computing device 1100, but any one or more of these components may be omitted or duplicated, as suitable for the application. In some embodiments, some or all of the components included in computing device 1100 may be attached to one or more printed circuit boards (e.g., a motherboard). In some embodiments, various ones of these components may be fabricated onto a single system-on-a-chip (SoC) die. Additionally, in various embodiments, computing device 1100 may not include one or more of the components illustrated in FIG. 11, but computing device 1100 may include interface circuitry for coupling to the one or more components. For example, computing device 1100 may not include a display device 1103, but may include display device interface circuitry (e.g., a connector and driver circuitry) to which display device 1103 may be coupled. In another set of examples, computing device 1100 may not include an audio output device 1104, other output device 1105, global positioning system (GPS) device 1109, audio input device 1110, or other input device 1111, but may include audio output device interface circuitry, other output device interface circuitry, GPS device interface circuitry, audio input device interface circuitry, audio input device interface circuitry, to which audio output device 1104, other output device 1105, GPS device 1109, audio input device 1110, or other input device 1111 may be coupled.

Computing device 1100 may include a processing device 1101 (e.g., one or more processing devices). As used herein, the term “processing device” or “processor” indicates a device that processes electronic data from registers and/or memory to transform that electronic data into other electronic data that may be stored in registers and/or memory. Processing device 1101 may include a memory 1121, a communication device 1122, a refrigeration device 1123, a battery/power regulation device 1124, logic 1125, interconnects 1126 (i.e., optionally including redistribution layers (RDL) or metal-insulator-metal (MIM) devices), a heat regulation device 1127, and a hardware security device 1128.

Processing device 1101 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1100 may include a memory 1102, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1102 includes memory that shares a die with processing device 1101. This memory may be used as cache memory and may include embedded dynamic random-access memory (eDRAM) or spin transfer torque magnetic random-access memory (STT-MRAM).

Computing device 1100 may include a heat regulation/refrigeration device 1106. Heat regulation/refrigeration device 1106 may maintain processing device 1101 (and/or other components of computing device 1100) at a predetermined low temperature during operation.

In some embodiments, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1107 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1107 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1107 may operate in accordance with other wireless protocols in other embodiments. Computing device 1100 may include an antenna 1113 to facilitate wireless communications and/or to receive other wireless communications (such as AM or FM radio transmissions).

In some embodiments, communication chip 1107 may manage wired communications, such as electrical, optical, or any other suitable communication protocols (e.g., the Ethernet). As noted above, communication chip 1107 may include multiple communication chips. For instance, a first communication chip 1107 may be dedicated to shorter-range wireless communications such as Wi-Fi or Bluetooth, and a second communication chip 1107 may be dedicated to longer-range wireless communications such as GPS, EDGE, GPRS, CDMA, WiMAX, LTE, EV-DO, or others. In some embodiments, a first communication chip 1107 may be dedicated to wireless communications, and a second communication chip 1107 may be dedicated to wired communications.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a GPS device 1109 (or corresponding interface circuitry, as discussed above). GPS device 1109 may be in communication with a satellite-based system and may receive a location of computing device 1100, as known in the art.

Computing device 1100 may include other output device 1105 (or corresponding interface circuitry, as discussed above). Examples of the other output device 1105 may include an audio codec, a video codec, a printer, a wired or wireless transmitter for providing information to other devices, or an additional storage device.

Computing device 1100 may include other input device 1111 (or corresponding interface circuitry, as discussed above). Examples of the other input device 1111 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, access list management, malware detection, or spyware detection.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-11. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a source body and a drain body in a transistor structure, and a stack of nanoribbons coupling the source body with the drain body, wherein a first of the nanoribbons has a first thickness at a midpoint between the source body and the drain body, and has a second thickness at an intervening point between the midpoint and one of the source body or the drain body, and the first thickness is at least 5% greater than the second thickness.

In one or more second embodiments, further to the first embodiments, the transistor structure is a first transistor structure, the source and drain bodies are first source and drain bodies, the stack of nanoribbons is a first stack of first nanoribbons, and the apparatus also includes second source and drain bodies in a second transistor structure, a second stack of second nanoribbons between and coupling the second source and drain bodies, wherein a first thickness variation in the first of the first nanoribbons is greater than a second thickness variation in the first of the second nanoribbons, the first nanoribbons include a first semiconductor element, the second nanoribbons include a second semiconductor element, and the first semiconductor element is absent in the second nanoribbons.

In one or more third embodiments, further to the first or second embodiments, the first thickness variation is ten times or more than the second thickness variation.

In one or more fourth embodiments, further to the first through third embodiments, a first centerline through the first of the first nanoribbons is coplanar with a second centerline through the first of the second nanoribbons, the first nanoribbons have a first pitch, and the second nanoribbons have the first pitch.

In one or more fifth embodiments, further to the first through fourth embodiments, the first nanoribbons include silicon and germanium, and the second nanoribbons consist essentially of silicon.

In one or more sixth embodiments, further to the first through fifth embodiments, a surface of the first of the nanoribbons over the midpoint has a first concentration of germanium, the first of the nanoribbons has a second concentration of germanium on a centerline at the midpoint, and the first concentration of germanium is within 5% of the second concentration of germanium.

In one or more seventh embodiments, further to the first through sixth embodiments, a first concentration of germanium adjacent an interface between the first of the first nanoribbons is less than a second concentration of germanium in one of the first source or drain bodies and less than a third concentration of germanium in the first of the first nanoribbons.

In one or more eighth embodiments, further to the first through seventh embodiments, the midpoint is a first midpoint, the first of the second nanoribbons has a third thickness at a second midpoint between the second source and drain bodies, and the first thickness is at least 5% greater than the third thickness.

In one or more ninth embodiments, further to the first through eighth embodiments, the first of the nanoribbons includes a first atomic composition at the midpoint, the first of the nanoribbons includes a second atomic composition at the intervening point, and the first and second atomic compositions are approximately equal.

In one or more tenth embodiments, an apparatus includes a first transistor structure, including a first stack of first nanoribbons between and coupling first source and drain bodies, wherein a first thickness of a first of the first nanoribbons is at least 3% greater than a second thickness of the first of the first nanoribbons, the first thickness at a midpoint between the first source and drain bodies, and a second transistor structure, including a second stack of second nanoribbons between and coupling second source and drain bodies, wherein a maximum thickness of a first of the second nanoribbons is not more than 1% more than a minimum thickness of the first of the second nanoribbons.

In one or more eleventh embodiments, further to the tenth embodiments, the first and second nanoribbons include silicon, the first nanoribbons include germanium, and germanium is absent in the second nanoribbons.

In one or more twelfth embodiments, further to the tenth or eleventh embodiments, the first of the first nanoribbons and the first of the second nanoribbons are coplanar, the first stack includes a first pitch between the first nanoribbons, and the second stack includes the first pitch between the second nanoribbons.

In one or more thirteenth embodiments, further to the tenth through twelfth embodiments, the first of the first nanoribbons has a first germanium concentration on a centerline at the midpoint, the first of the first nanoribbons has a second germanium concentration on a surface over the midpoint, and the first germanium concentration is within 5% of the second germanium concentration.

In one or more fourteenth embodiments, a method includes depositing a material layer over a stack of nanoribbons, wherein the nanoribbons are between and coupling source and drain bodies, the nanoribbons include a first element, and the material layer includes a second element, encasing the nanoribbons and the material layer in a retaining layer, and diffusing the second element into the nanoribbons.

In one or more fifteenth embodiments, further to the fourteenth embodiments, also including thinning the nanoribbons to a thickness of approximately 2 nm by isotropically etching the nanoribbons.

In one or more sixteenth embodiments, further to the fourteenth or fifteenth embodiments, the depositing the material layer over the stack of nanoribbons includes epitaxially depositing at least the second element over individual ones of the nanoribbons.

In one or more seventeenth embodiments, further to the fourteenth through sixteenth embodiments, the depositing the material layer over the stack of nanoribbons includes depositing the first and second elements to between half a thickness of the nanoribbons and one-and-a-half times the thickness of the nanoribbons.

In one or more eighteenth embodiments, further to the fourteenth through seventeenth embodiments, the encasing the nanoribbons and the material layer in the retaining layer includes conformally depositing silicon and nitrogen around each of the nanoribbons.

In one or more nineteenth embodiments, further to the fourteenth through eighteenth embodiments, the encasing the nanoribbons and the material layer in the retaining layer conformally deposits the retaining layer to a first thickness of at least 0.5 nm and not more than a second thickness of the nanoribbons.

In one or more twentieth embodiments, further to the fourteenth through nineteenth embodiments, also including growing an interface layer on an end of a first of the nanoribbons, and epitaxially growing the source body or the drain body from the interface layer, wherein after the diffusing the second element into the nanoribbons the interface layer has a first concentration of the second element less than a second concentration of the second element in the source or drain body epitaxially grown from the interface layer and less than a third concentration of the second element in the first of the nanoribbons.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a source body and a drain body in a transistor structure; and
a stack of nanoribbons coupling the source body with the drain body, wherein a first of the nanoribbons has a first thickness at a midpoint between the source body and the drain body, and has a second thickness at an intervening point between the midpoint and one of the source body or the drain body, and the first thickness is at least 5% greater than the second thickness.

2. The apparatus of claim 1, wherein:
the transistor structure is a first transistor structure;
the source and drain bodies are first source and drain bodies;
the stack of nanoribbons is a first stack of first nanoribbons; and
the apparatus further comprises:
second source and drain bodies in a second transistor structure;
a second stack of second nanoribbons between and coupling the second source and drain bodies, wherein:
a first thickness variation in the first of the first nanoribbons is greater than a second thickness variation in the first of the second nanoribbons;
the first nanoribbons comprise a first semiconductor element;
the second nanoribbons comprise a second semiconductor element; and
the first semiconductor element is absent in the second nanoribbons.

3. The apparatus of claim 2, wherein the first thickness variation is ten times or more than the second thickness variation.

4. The apparatus of claim 2, wherein a first centerline through the first of the first nanoribbons is coplanar with a second centerline through the first of the second nanoribbons, the first nanoribbons have a first pitch, and the second nanoribbons have the first pitch.

5. The apparatus of claim 2, wherein:
the first nanoribbons comprise silicon and germanium; and
the second nanoribbons consist essentially of silicon.

6. The apparatus of claim 5, wherein:
a surface of the first of the nanoribbons over the midpoint has a first concentration of germanium;
the first of the nanoribbons has a second concentration of germanium on a centerline at the midpoint; and
the first concentration of germanium is within 5% of the second concentration of germanium.

7. The apparatus of claim 5, wherein a first concentration of germanium adjacent an interface between the first of the first nanoribbons is less than a second concentration of germanium in one of the first source or drain bodies and less than a third concentration of germanium in the first of the first nanoribbons.

8. The apparatus of claim 2, wherein:
the midpoint is a first midpoint;
the first of the second nanoribbons has a third thickness at a second midpoint between the second source and drain bodies; and
the first thickness is at least 5% greater than the third thickness.

9. The apparatus of claim 1, wherein:
the first of the nanoribbons comprises a first atomic composition at the midpoint;
the first of the nanoribbons comprises a second atomic composition at the intervening point; and
the first and second atomic compositions are approximately equal.

10. An apparatus, comprising:
a first transistor structure, comprising a first stack of first nanoribbons between and coupling first source and drain bodies, wherein a first thickness of a first of the first nanoribbons is at least 3% greater than a second thickness of the first of the first nanoribbons, the first thickness at a midpoint between the first source and drain bodies; and
a second transistor structure, comprising a second stack of second nanoribbons between and coupling second source and drain bodies, wherein a maximum thickness of a first of the second nanoribbons is not more than 1% more than a minimum thickness of the first of the second nanoribbons.

11. The apparatus of claim 10, wherein:
the first and second nanoribbons comprise silicon;
the first nanoribbons comprise germanium; and
germanium is absent in the second nanoribbons.

12. The apparatus of claim 11, wherein:
the first of the first nanoribbons and the first of the second nanoribbons are coplanar;
the first stack comprises a first pitch between the first nanoribbons; and
the second stack comprises the first pitch between the second nanoribbons.

13. The apparatus of claim 12, wherein:
the first of the first nanoribbons has a first germanium concentration on a centerline at the midpoint;
the first of the first nanoribbons has a second germanium concentration on a surface over the midpoint; and
the first germanium concentration is within 5% of the second germanium concentration.

14. A method, comprising:
depositing a material layer over a stack of nanoribbons, wherein the nanoribbons are between and coupling source and drain bodies, the nanoribbons comprise a first element, and the material layer comprises a second element;
encasing the nanoribbons and the material layer in a retaining layer; and
diffusing the second element into the nanoribbons.

15. The method of claim 14, further comprising thinning the nanoribbons to a thickness of approximately 2 nm by isotropically etching the nanoribbons.

16. The method of claim 14, wherein the depositing the material layer over the stack of nanoribbons comprises epitaxially depositing at least the second element over individual ones of the nanoribbons.

17. The method of claim 14, wherein the depositing the material layer over the stack of nanoribbons comprises depositing the first and second elements to between half a thickness of the nanoribbons and one-and-a-half times the thickness of the nanoribbons.

18. The method of claim 14, wherein the encasing the nanoribbons and the material layer in the retaining layer comprises conformally depositing silicon and nitrogen around each of the nanoribbons.

19. The method of claim 18, wherein the encasing the nanoribbons and the material layer in the retaining layer conformally deposits the retaining layer to a first thickness of at least 0.5 nm and not more than a second thickness of the nanoribbons.

20. The method of claim 14, further comprising growing an interface layer on an end of a first of the nanoribbons, and epitaxially growing the source body or the drain body from the interface layer, wherein after the diffusing the second element into the nanoribbons the interface layer has a first concentration of the second element less than a second concentration of the second element in the source or drain body epitaxially grown from the interface layer and less than a third concentration of the second element in the first of the nanoribbons.
